(19) United States
(12) Patent Application Publication
(10) Pub. No.: US 2007/0032013 A1
(43) Pub. Date: Feb. 8, 2007

(54) METHODS OF FORMING A METAL OXIDE LAYER INCLUDING ZIRCONIUM OXIDE AND METHODS OF FORMING A CAPACITOR FOR SEMICONDUCTOR DEVICES INCLUDING THE SAME

(75) Inventors: Kyoung-Ryul Yoon, Gyeonggi-do (KR); Young-Geun Park, Gyeonggi-do (KR); Ki-Vin Im, Gyeonggi-do (KR); Jae-Hyun Yeo, Gyeonggi-do (KR); Eun-Ae Chung, Gyeonggi-do (KR); Young-Sun Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/462,405

(22) Filed: Aug. 4, 2006

(30) Foreign Application Priority Data
Aug. 5, 2005 (KR) 10-2005-0071636

(51) Int. Cl. H01L 21/8242

(52) U.S. Cl. 438/240; 438/287; 438/785

(57) ABSTRACT

The present invention provides methods of forming a metal oxide layer and methods of forming a capacitor including the same. The methods of forming the metal oxide include forming a thin layer including a metal oxide, such as zirconium oxide, on a substrate and performing a post-treatment on the thin layer at a temperature at which oxygen present in the metal oxide is hindered from being diffused in the thin layer. Consequently, reduced amounts of byproducts are present on the boundary surface of the thin layer and the substrate thereby improving electrical characteristics of the thin layer.

### CROSS-REFERENCE TO RELATED APPLICATION

This application claims priority to Korean Patent Application No. 10-2005-71636, filed Aug. 5, 2005, the disclosure of which is hereby incorporated by reference in its entirety.

### FIELD OF THE INVENTION

Embodiments of the present invention relate to methods of forming a metal oxide layer and methods of forming a capacitor for semiconductor devices including the same. More particularly, embodiments of the present invention relate to methods of forming a metal oxide layer including zirconium oxide and to methods of forming a capacitor for semiconductor devices including the same.

### BACKGROUND OF THE INVENTION

A thin layer in a semiconductor device having a high integration degree usually includes a high dielectric constant material, i.e., a “high-k” material. For example, a gate insulation layer of a metal-oxide semiconductor (MOS) transistor, a dielectric layer of a capacitor in a semiconductor device and a dielectric layer in a flash memory device may include the high-k material. The gate insulation layer including the high-k material may minimize current leakage between a gate conductive layer and a channel in the MOS transistor and may have a relatively small equivalent oxide thickness (EOT). The dielectric layer of the capacitor including the high-k material may also minimize current leakage between upper and lower electrodes of the capacitor. In addition, the dielectric layer of the flash memory device including the high-k material may improve the coupling ratio in the flash memory device.

Examples of the high-k material include tantalum oxide (Ta₂O₅), yttrium oxide (Y₂O₃), hafnium oxide (HfO₂), zirconium oxide (ZrO₂), niobium oxide (Nb₂O₅), barium titanium oxide (BaTiO₃) and strontium titanium oxide (SrTiO₃).

Among these exemplary high-k materials, hafnium oxide (HfO₂) has been very widely used as the high-k material for semiconductor devices. U.S. Pat. No. 6,348,386 discusses a method of forming a thin layer comprising hafnium oxide for a semiconductor device. However, the thin layer comprising hafnium oxide may be difficult to form to possess an EOT of less than or equal to about 12 Å so that the hafnium oxide has several limitations when applied to newer semiconductor devices requiring a design rule of about 60 nm.

Thus, zirconium oxide may be used as the high-k material for a thin layer in a semiconductor device such as the gate insulation layer of a MOS transistor, the dielectric layer of a capacitor in a semiconductor device and the dielectric layer in a flash memory device. The zirconium oxide layer may be more readily formed to possess an EOT less than or equal to about 10 Å. Particularly, a dielectric constant of the zirconium oxide ranges from about 25 to about 38; thus, zirconium oxide may be employed to provide a thin layer for a semiconductor device instead of hafnium oxide when considering the dielectric constant.

Exemplary methods of forming a thin layer including zirconium oxide for use in a semiconductor device are discussed in U.S. Pat. No. 6,800,519 and Korean Patent Laid-Open Publication No. 2005-8319. The zirconium oxide layer is formed on a substrate by a sputtering process, a chemical vapor deposition (CVD) process, an atomic layer deposition (ALD) process, etc.

A reactant including a zirconium precursor and an oxidizing agent for oxidizing the reactant may be used in an ALD process for forming the zirconium oxide layer. More specifically, a composition ratio of zirconium and oxygen may be optimized in a process for forming the zirconium oxide layer, which may improve electrical characteristics of the zirconium oxide layer. Conventionally, optimization of the composition ratio of zirconium and oxygen may be performed by increasing the concentration and/or amount of the oxidizing agent during the ALD process. However, the increase in concentration and/or the amount of the oxidizing agent during the ALD process may detrimentally affect the step coverage of the zirconium oxide layer.

More recently, a post-treatment has been performed on the zirconium oxide layer immediately after forming the zirconium oxide layer on the substrate in an attempt to solve the problems described above. In the post-treatment process, the composition ratio of zirconium and oxygen may be optimized in the zirconium oxide layer, and carbon (C) may be removed from the zirconium oxide layer. U.S. Pat. No. 6,800,519 referenced above indicates that the post-treatment is performed at a temperature of about 650° C. on the zirconium oxide layer after completing the zirconium oxide layer, and Korean Patent Laid-Open Publication No. 2005-8319 referenced above indicates that the post-treatment is performed at a temperature of about 450° C. on the zirconium oxide layer after completing the zirconium oxide layer.

However, these post-treatment processes may present several problems. For example, when the post-treatment is performed at a temperature higher than or equal to about 300° C. on the zirconium oxide layer, oxygen in the zirconium oxide layer may actively diffuse into the zirconium oxide layer, and may chemically react with the material underlying the zirconium oxide layer. That is, material underlying the zirconium oxide layer may be readily oxidized due, at least in part, to the diffusion of oxygen into the zirconium oxide layer. The oxidation of material underlying the zirconium oxide layer may produce byproducts of the oxidation reaction at a boundary surface of the zirconium oxide layer and the underlying layer thereof. The byproducts of the oxidation reaction at the boundary surface may increase the leakage current from the zirconium oxide layer and may also reduce the uniformity of the EOT of the zirconium oxide layer.

### SUMMARY OF THE INVENTION

Embodiments of the present invention provide methods of forming a metal oxide layer in which a composition ratio of the metal and oxygen is sufficiently optimized. Embodiments of the present invention also provide methods of forming a capacitor for a semiconductor device involving the methods of forming the metal oxide layer as described herein.

According to some embodiments of the present invention, methods of forming a metal oxide layer include forming a thin layer on a substrate, the thin layer including a metal oxide wherein a composition ratio of metal and oxygen in the metal oxide is about 1:2, and performing a post-treatment on the thin layer at a temperature to reduce diffusion of oxygen from the metal oxide into the thin layer. In some embodiments, the thin layer includes zirconium oxide. In some embodiments, the post-treatment is performed at a temperature in a range of about 10° C. to about 300° C., and other embodiments, in a range of about 20° C. to about 300° C., and in a range of about 10° C. to about 150° C. In some embodiments, the post-treatment includes a plasma oxidation treatment.

According to some embodiments of the present invention, methods of forming a zirconium oxide layer include forming a thin layer on a substrate, the thin layer including zirconium oxide, and performing a post-treatment on the thin layer at a temperature in a range of about 10° C. to about 150° C. using an atomic layer deposition process wherein a composition ratio of zirconium and oxygen in the zirconium oxide is about 1:2 to provide a zirconium oxide layer having reduced oxygen diffusion into the thin layer, a smaller equivalent oxide thickness or a combination thereof, compared to a zirconium oxide layer formed using a conventional process.

In some embodiments, methods of forming a capacitor for a semiconductor device include forming a lower electrode on a substrate; forming a thin layer on the lower electrode, wherein the thin layer includes zirconium oxide; performing a post-treatment on the thin layer at a temperature wherein a reduction of diffusion of oxygen from the zirconium oxide into the thin layer results and a composition ratio of zirconium and oxygen in the zirconium oxide is about 1:2 to provide a dielectric layer; and forming an upper electrode on the dielectric layer.

Embodiments of the present invention further provide methods of forming a capacitor for a semiconductor device, including forming a mold layer on a semiconductor substrate, wherein the mold layer has an opening through which the substrate is at least partially exposed; forming a first thin layer on side and bottom surfaces of the opening and a top surface of the mold layer, wherein the first thin layer includes titanium nitride; forming a sacrificial layer on a resultant structure including the first thin layer to a thickness to fill the opening; removing the sacrificial layer and the first thin layer to expose a top surface of the mold layer wherein the sacrificial layer and the first thin layer remain in the opening thereby providing a node separation of the first thin layer; removing a residual sacrificial layer in the opening and the mold layer from the substrate wherein the node-separated first thin layer is formed into a lower electrode; forming a second thin layer on the lower electrode to a substantially uniform thickness by an atomic layer deposition (ALD) process, wherein the second thin layer includes zirconium oxide; performing a post-treatment on the second thin layer at a temperature of in a range of about 10° C. to about 150° C., wherein a composition ratio of zirconium and oxygen in the zirconium oxide is about 1:2 thereby transforming the second thin layer into a dielectric layer; and forming an upper electrode on the dielectric layer.

According to embodiments of the present invention, an additional performance of a post-treatment after a formation of a metal oxide layer at a lower temperature may sufficiently improve electrical characteristics of the metal oxide layer.

### BRIEF DESCRIPTION OF THE DRAWINGS

The above and other features and advantages of the present invention will become readily apparent by reference to the following detailed description when considering such in conjunction with the accompanying drawings, in which:

FIGS. 1A to 1E present cross-sectional views illustrating procedures used in a method of forming a metal oxide layer according to some embodiments of the present invention;

FIG. 2 presents a cross-sectional view illustrating a metal layer according to some embodiments of the present invention;

FIGS. 3A to 3I present cross-sectional views illustrating procedures used in a method of forming a capacitor for a semiconductor device according to some embodiments of the present invention;

FIGS. 4 and 5 present graphs showing a change in the leakage current in accordance with a voltage applied to the capacitor including a conventional dielectric layer; and

FIG. 6 presents a graph showing a change in the leakage current in accordance with a voltage applied to the capacitor including a dielectric layer according to some embodiments of the present invention.

The present invention will now be described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will convey the scope of the invention to those skilled in the art.

### DETAILED DESCRIPTION

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise. Also, as used herein, “and/or” refers to and encompasses any and all possible combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y .”

Unless otherwise defined, all terms, including technical and scientific terms used in this description, have the same meaning as commonly understood by one of ordinary skill in the art to which this invention belongs. All publications, patent applications, patents, and other references mentioned herein are incorporated by reference in their entirety.

It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Moreover, it will be understood that steps comprising the methods provided herein can be performed independently or at least two steps can be combined. Additionally, steps comprising the methods provided herein, when performed independently or combined, can be performed at the same temperature and/or atmospheric pressure or at different temperatures and/or atmospheric pressures without departing from the teachings of the present invention.

In the drawings, the thickness of layers and regions are exaggerated for clarity. It will also be understood that when a layer is referred to as being “on” another layer or substrate or a reactant is referred to as being introduced, exposed or feed “onto” another layer or substrate, it can be directly on the other layer or substrate, or intervening layers can also be present. However, when a layer, region or reactant is described as being “directly on” or introduced, exposed or feed “directly onto” another layer or region, no intervening layers or regions are present. Additionally, like numbers refer to like compositions or elements throughout.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the present invention are further described herein with reference to cross-section illustrations that are schematic illustrations of idealized embodiments of the present invention. As such, variations from the shapes of the illustrations as a result, for example, of manufacturing techniques and/or tolerances, are to be expected. In particular, the regions illustrated in the figures are schematic in nature and their shapes are not intended to illustrate the precise shape of a region of a device and are not intended to limit the scope of the present invention.

As will be appreciated by one of ordinary skill in the art, the present invention may be embodied as compositions and devices including the compositions as well as methods of making and using such compositions and devices.

Methods of Forming a Metal Oxide Layer

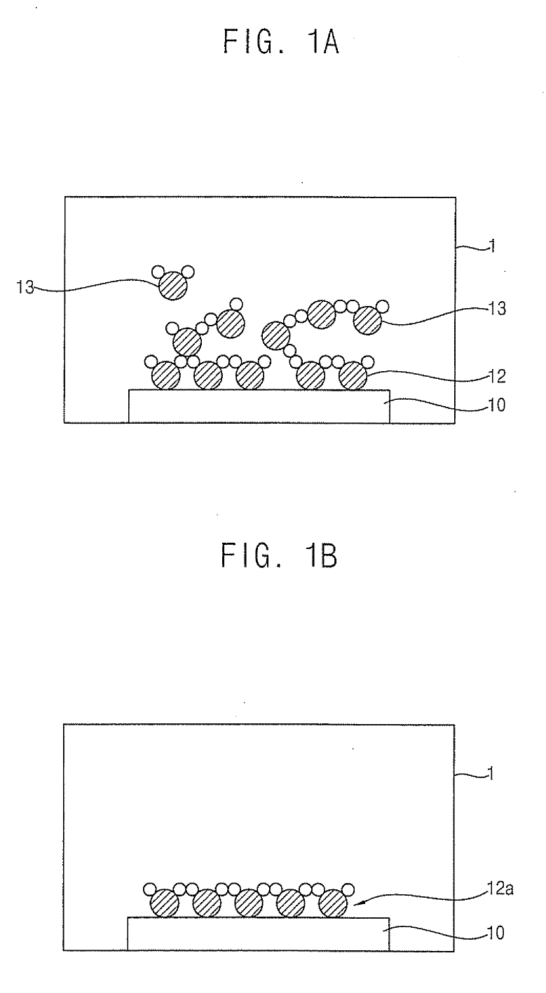

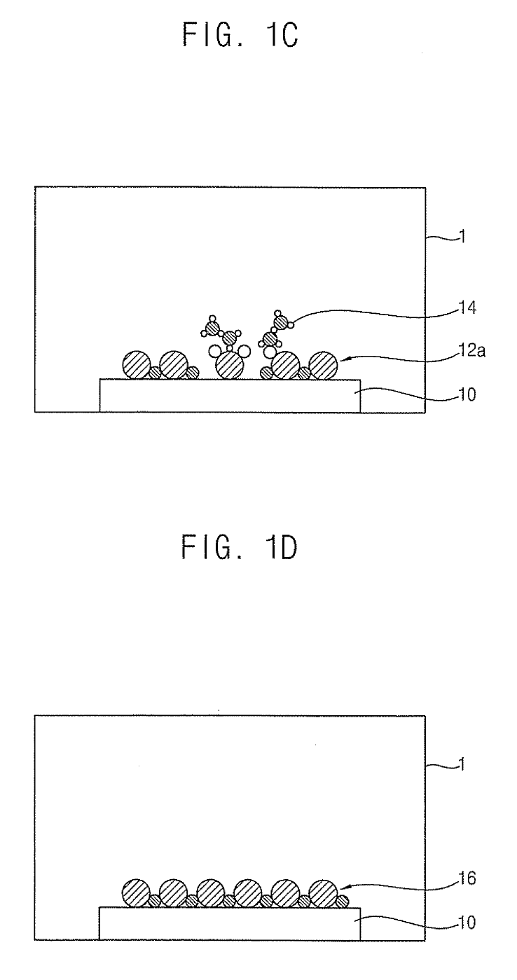

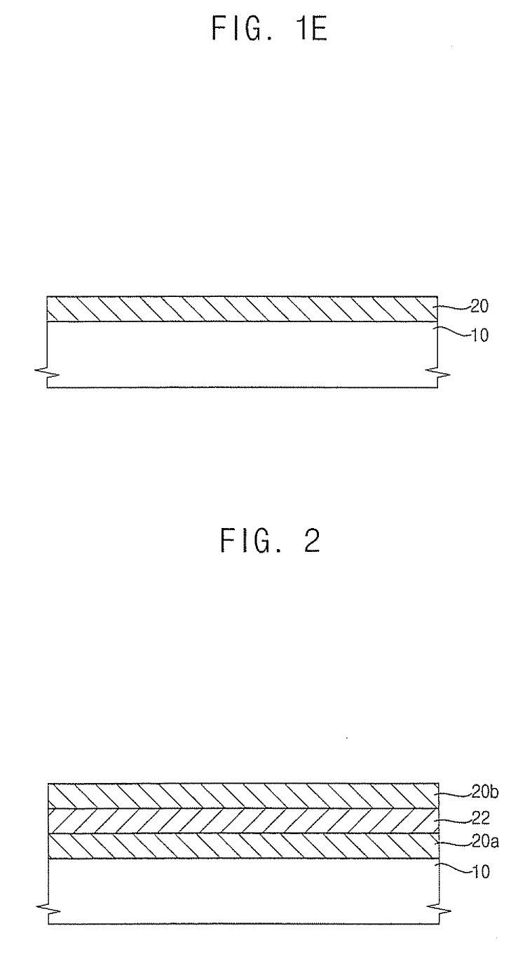

FIGS. 1A to 1E present cross-sectional views illustrating the process of forming a metal oxide layer according to some embodiments of the present invention. According to some embodiments, the metal oxide layer may be formed on a substrate through a suitable deposition process. In particular embodiments, the deposition process is an atomic layer deposition (ALD) process. The ALD process may be utilized instead of a sputtering process or a chemical vapor deposition (CVD) process. In some embodiments, a zirconium oxide layer may be utilized as the metal oxide layer. The present invention, however, can include other oxide layers deposited through various deposition processes as suitable to achieve the desired result.

Referring to FIG. 1A, a semiconductor substrate 10 is positioned in a chamber 1 in which an ALD process is performed. When the temperature inside the chamber 1 is less than about 200° C., the reactants of the ALD process may not be sufficiently activated, which may reduce the efficiency of the ALD process. When the temperature inside the chamber 1 is more than about 400° C., the thin layer on the substrate 10 may tend to crystallize. In particular, the ALD process may exhibit some characteristics of a CVD process when the processing temperature is over about 400° C. Thus, the temperature inside the chamber 1 may be maintained at a temperature no greater than about 400° C. Accordingly, the temperature inside the chamber 1 may be maintained at a temperature in a range of about 200° C. to about 400° C. In some embodiments of the present invention, the temperature inside the chamber 1 may be maintained at a temperature of about 300° C. Also, when the inner pressure of the chamber 1 is less than about 0.1 Torr, the reactants of the ALD process may not be sufficiently activated, which may reduce the efficiency of the ALD process. When the inner pressure of the chamber 1 is greater than about 3.0 Torr, the processing rate may be rapid to the extent that the ALD process may be difficult to accurately control. Accordingly the chamber 1 may be maintained at a pressure in a range of about 0.1 Torr to about 3.0 Torr.

When completing the pressure and temperature adjustments of the chamber 1 based on the above-mentioned pressure and temperature ranges, the reactants of the ALD process may be supplied onto the substrate 10 in the chamber 1. In some embodiments of the present invention, the reactant is supplied into the chamber 1 in a gaseous state, for example, using a bubbler.

The reactants may include a zirconium precursor so as to form a thin layer including zirconium oxide on the substrate 10. Examples of the reactants including the zirconium precursor include zirconium butoxide (Zr(OtBu)₄), tetrakis ethylmethylamino zirconium (TEMAZ, Zr[N(CH₃)(C₂H₅)₄]), zirconium ethoxide (Zr(OEt)₄), zirconium isopropoxide (Zr(OC₃H₇)₄), tetramethyl heptanedionato zirconium (Zr [TMHD]₄, Zr(C₁₁H₁₉O₂)₄)), etc. These reactants may be used alone or in combination thereof. In some embodiments of the present invention, TEMAZ is utilized as the reactant including the zirconium precursor. In some embodiments, the reactant is supplied onto the substrate 10 for a time period in a range of about 0.5 s to about 7 s. In other embodiments, the reactant is provided onto the substrate 10 for a time period in a range of about 2 s to about 5 s. A first portion 12 of the reactant may be chemisorbed onto the substrate 10, and a second portion 13 of the reactant, which is a residual of the reactant excluding the first portion 12, may be physisorbed onto the first portion 12 of the reactant, or may drift into the chamber 1.

Referring to FIG. 1B, a first purge gas may be supplied into the chamber 1 for a period of time in a range of about 0.5 s to about 20 s, and a first purge process may be performed in the chamber 1. In some embodiments of the present invention, the first purge gas may include an inert gas, for example, argon (Ar) gas or a nitrogen (N₂) gas.

The second portion 13 of the reactant may be removed from the chamber 1 by the first purge process so that the first portion 12 of the reactant remains on the substrate 10. More specifically, in some embodiments, zirconium precursor molecules 12a remain on the substrate 10 from the first purge process.

In some embodiments of the present invention, removal of the second portion 13 of the reactant from the chamber 1 may be performed by a vacuum process as an alternative to, or in conjunction with, the first purge process. In some embodiments, when the chamber 1 is maintained in a vacuum state for a period of time in a range of about 2 s to about 10 s, the second portion 13 of the reactant may also be removed from the chamber 1.

Referring to FIG. 1C, an oxidizing agent 14 may be supplied into the chamber 1 for a period of time in a range of about 1 s to about 40 s. Examples of the oxidizing agent 14 may include ozone (O₃), oxygen (O₂), water vapor (H₂O), plasma-activated oxygen (O₂), remote plasma-activated oxygen (O₂), etc. These oxidizing agents can be used alone or in combination thereof. In some embodiments, an ozone (O₃) gas is used as the oxidizing agent 14. The ozone gas may be provided for a time period in a range from about 5 s to about 35 s, and in some embodiments, for a period of time in a range of about 5 s to about 30 s. The oxidizing agent 14 may be chemically reacted with the zirconium precursor molecules 12a that are chemisorbed onto the substrate 10 thereby oxidizing the zirconium precursor molecules 12a.

Referring to FIG. 1D, a second purge gas may be supplied into the chamber 1 for the same or substantially the same time as the first purge process, and a second purge process may be performed in the chamber 1. In some embodiments, the second purge gas is the same as or substantially similar to the first purge gas. A residual oxidizing agent remaining in the chamber 1, which has not reacted with the zirconium precursor molecules 12a, may be removed from the chamber 1 by the second purge process so that a solid material including zirconium oxide 16 may be produced on the substrate 10.

Referring to FIG. 1E ; the processes described above with reference to FIGS. 1A to 1D are completed on at least a significant portion of the surface of the substrate 10 so that at least a significant portion of the surface of the substrate 10 may be covered with zirconium oxide 16, thereby forming a thin layer 20 including zirconium oxide 16 on the substrate 10. Sequential performance of the above-mentioned processes may complete a cycle of an ALD process. The thickness of the thin layer may be determined by repetition of the cycles of the ALD process.

Thereafter, a post-treatment may be performed on the thin layer 20, thereby improving electrical characteristics of the thin layer 20. The post-treatment may optimize the composition ratio of zirconium and oxygen in the zirconium oxide 16, and may also remove impurities, such as carbon (C) 1 from the thin layer 20.

When the post-treatment is performed at a temperature less than about 10° C., the composition ratio of zirconium and oxygen included in the zirconium oxide 16 may be problematic to adjust, and impurities, such as carbon (C), included in the thin layer 20 may be difficult to remove. Further, when the post-treatment is performed at a temperature higher than about 150° C., oxygen in the zirconium oxide may diffuse in all directions in the thin layer 20 and may also react with the substrate 10 under the thin layer 20 so that byproducts of the reaction may be produced at the boundary surface of the thin layer 20 and the substrate 10. Accordingly, the post-treatment may be performed at a temperature in a range of about 10° C. to about 150° C., and more particularly, at a temperature in a range of about 18° C. to about 100° C. In some embodiments, the post-treatment is performed at a temperature in a range of about 18° C. to about 50° C.

A plasma oxidation process may be performed as the post-treatment for activating the reactant. The post-treatment may be performed at a temperature in a range of about 10° C. to about 150° C. According to some embodiments, oxygen gas is utilized as a source gas, and an inert gas is utilized as a carrier gas during the plasma oxidation process. The oxygen gas and the inert gas are provided at a volume ratio in a range of about 1:1 to about 20:1. As a result, when the oxygen gas is provided at a volume ratio in a range of about 0.5 standard liters per minute (s lm) to about 2.0 slm, the inert gas may be provided at a volume ratio in a range of about 0.1 slm to about 0.5 slm. In some embodiments, nitrogen gas may be utilized as the inert gas. The plasma oxidation process may be performed at a pressure in a range of about 10 Pa to about 300 Pa under an applied power in a range of about 50 W to about 100 W.

In some embodiments, the plasma oxidation process is performed at a temperature in a range of about 10° C. to about 150° C. and a pressure in a range of about 10 Pa to about 300 Pa for a period of time in a range of about 10 s to about 3,600 s by providing oxygen gas and an inert gas at a volume ratio in a range of about 1:1 to about 20:1.

Under the process conditions described above, the composition ratio of zirconium and oxygen in the zirconium oxide is set to be about 1:2, and the impurities including carbon (C) may be sufficiently removed from the thin layer 20. In particular, the plasma oxidation process may be performed at a temperature in a range of about 10° C. to about 150° C. as the post-treatment so that oxygen in the zirconium oxide may be sufficiently inhibited or prevented from being diffused into the thin layer 20. As a result, an oxidation reaction of the substrate 10 due, at least in part, to the diffusion of oxygen may be sufficiently reduced or prevented in the post-treatment. Thus, few to no byproducts may be present on the boundary surface of the thin layer 20 and the substrate 10 thereby improving electrical characteristics of the thin layer 20.

In some embodiments, the invention provides a single layer-structured metal layer including zirconium oxide as the thin layer 20; however, in other embodiments, the thin layer may also be formed to provide a multilayer structure, such as a metal layer including zirconium oxide and aluminum oxide, as would be understood by those of ordinary skill in the art. Hereinafter, a multilayer-structured thin layer will be described in detail.

FIG. 2 presents a cross-sectional view illustrating a metal layer according to some embodiments of the present invention. Referring to FIG. 2, the metal layer may be formed into a multilayer structure including a zirconium oxide layer and an aluminum oxide layer. Particularly, the aluminum oxide layer 22 is interposed between the zirconium oxide layers 20a and 20b, similar to a sandwich. A lower zirconium oxide layer 20a is formed on the substrate 10 in the same or a substantially similar process as described with reference to FIGS. 1A to 1E.

Subsequently, an aluminum oxide layer 22 is formed on the lower zirconium oxide layer 20a. in some embodiments of the present invention, the lower zirconium oxide layer 20a is formed on the substrate 10 by an ALD process so that the aluminum oxide layer 22 is also formed through an ALD process as described below.

A reactant is supplied onto the substrate 10. The reactant may include an aluminum precursor, such as trimethyl aluminum (TMA, Al(CH₃)₃), which may be supplied onto the lower zirconium oxide layer 20a at the same or substantially the same temperature and pressure as the process for formation of the zirconium oxide layer 20a. The reactant may also be supplied in a gaseous state, for example, using a bubbler. A first portion of the reactant including an aluminum precursor may be chemisorbed onto the lower zirconium oxide layer 20a, a second portion thereof, which is a residual portion of the reactant including an aluminum precursor, but excluding the first portion thereof, may be physisorbed onto the first portion, or drifted into the chamber.

Subsequently, a first purge gas may be supplied into the chamber so that the second portion of the reactant including an aluminum precursor may be removed from the chamber. Accordingly, the aluminum precursor remains on the lower zirconium oxide layer 20a. In some embodiments, the same or a substantially similar first purge gas as in the process for formation of the zirconium oxide layer 20a may be supplied to the chamber for the same or substantially the same time as in the process for formation of the zirconium oxide layer 20a.

An oxidation agent may be supplied into the chamber and may be chemically reacted with the aluminum precursor on the lower zirconium oxide layer 20a thereby oxidizing the aluminum precursor. In some embodiments, the same or a substantially similar oxidation agent as in the process for formation of the zirconium oxide layer 20a may also be supplied to the chamber.

A second purge gas may be supplied into the chamber so that a residual oxidation agent, which may not be chemically reacted with the aluminum precursor in the chamber, may be removed from the chamber. Accordingly, a solid material including aluminum oxide may be produced on the lower zirconium oxide layer 20a. In some embodiments, the same or a substantially similar second purge gas as used in the process for formation of the lower zirconium oxide layer 20a may be supplied to the chamber for the same or substantially the same time as in the process for formation of the zirconium oxide layer 20a.

The procedures described above for the process for formation of the solid material including aluminum oxide may be performed at least once on a portion of the surface of the lower zirconium oxide layer 20a so that at least a significant portion of the surface of the lower zirconium oxide layer 20a may be covered with the aluminum oxide, thereby forming an aluminum oxide layer 22 on the lower zirconium oxide layer 20a.

Thereafter, an upper zirconium oxide layer 20b may be formed on the aluminum oxide layer 22 through the same or a substantially similar process as for formation of the lower zirconium oxide layer 20a, thereby forming the multilayer-structured metal oxide layer on the substrate 10.

A post-treatment may also be performed on the multilayer-structured metal oxide layer under the same or substantially similar conditions as in the post-treatment for formation of the single layer-structured metal oxide layer 20, thereby improving electrical characteristics of the multilayer-structured metal oxide layer. The post-treatment may be performed once after formation of the lower and upper zirconium oxide layers 20a and 20b, respectively, or the post-treatment may be performed more than once after the formation of the lower and upper zirconium oxide layers 20a and 20b.

The composition ratio of zirconium and oxygen in the lower and upper zirconium oxide layers 20a and 20b can be set to be about 1:2, and the impurities, including carbon (C), may be sufficiently removed from the lower and upper zirconium oxide layers 20a and 20b, thereby improving electrical characteristics of the multilayered-structured metal oxide layer. Additionally, crystallization of the aluminum oxide layer 22 may progress at a temperature of about 600° C. so that crystallization of the lower and upper zirconium oxide layers 20a and 20b may be reduced or prevented. Thus, the lower and upper zirconium oxide layers 20a and 20b may allow the multilayer-structured metal oxide layer to have a high dielectric constant and/or a small equivalent oxide thickness (EOT), as well as a high crystallization temperature due, at least in part, to the aluminum oxide layer 22.

Methods of Forming a Capacitor for Semiconductor Devices

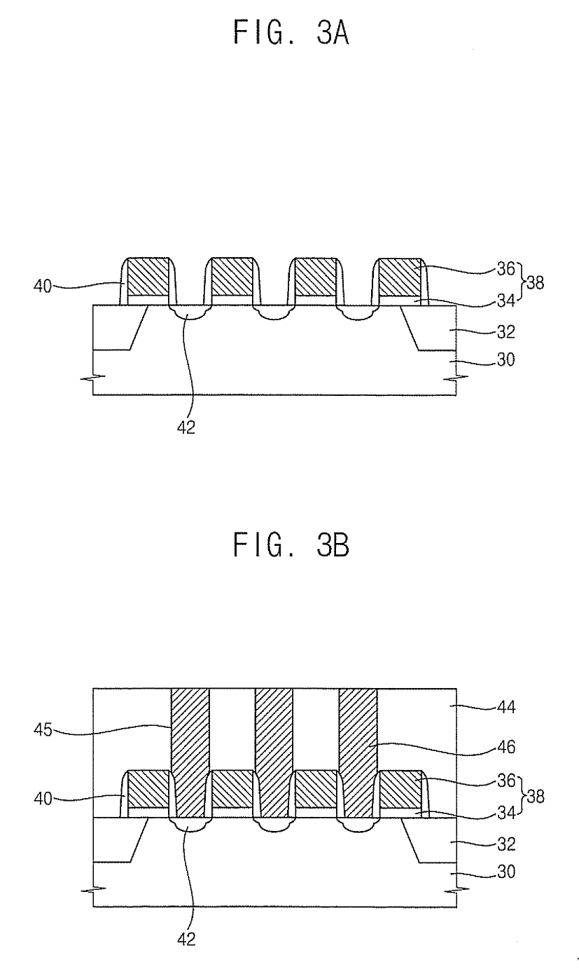

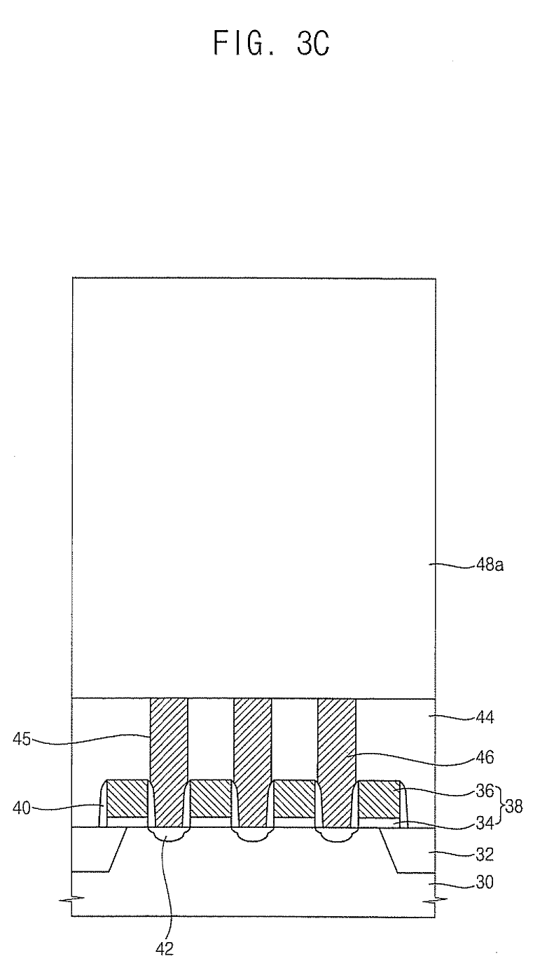

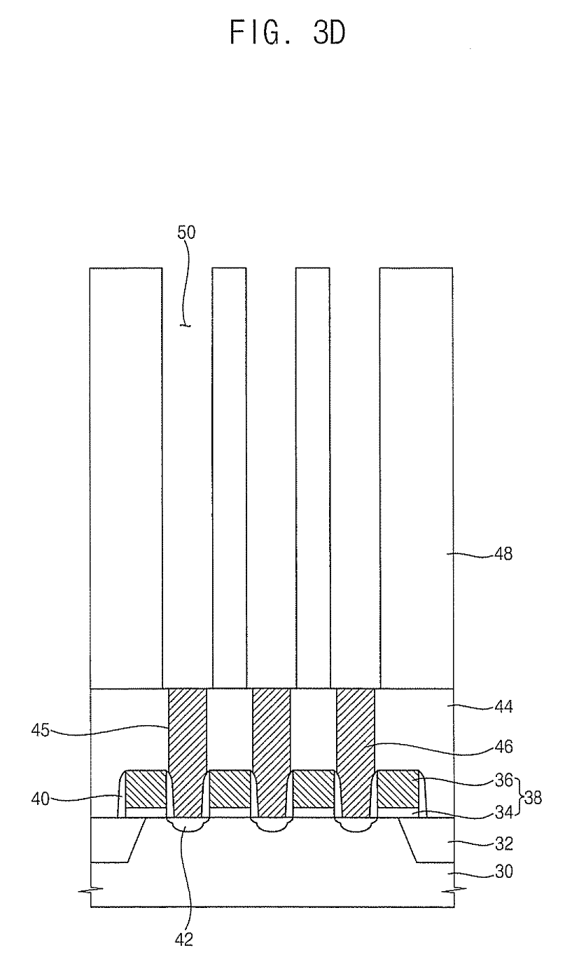

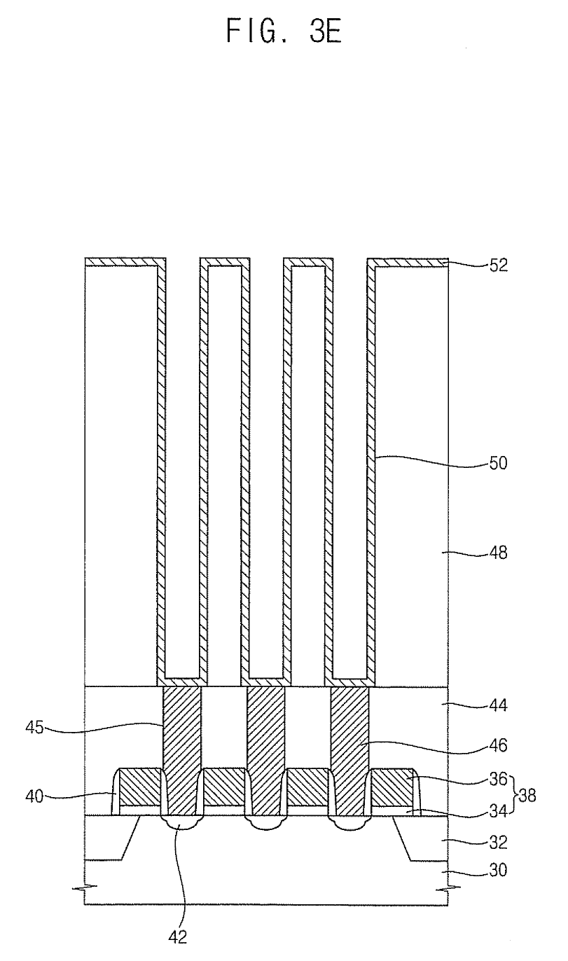

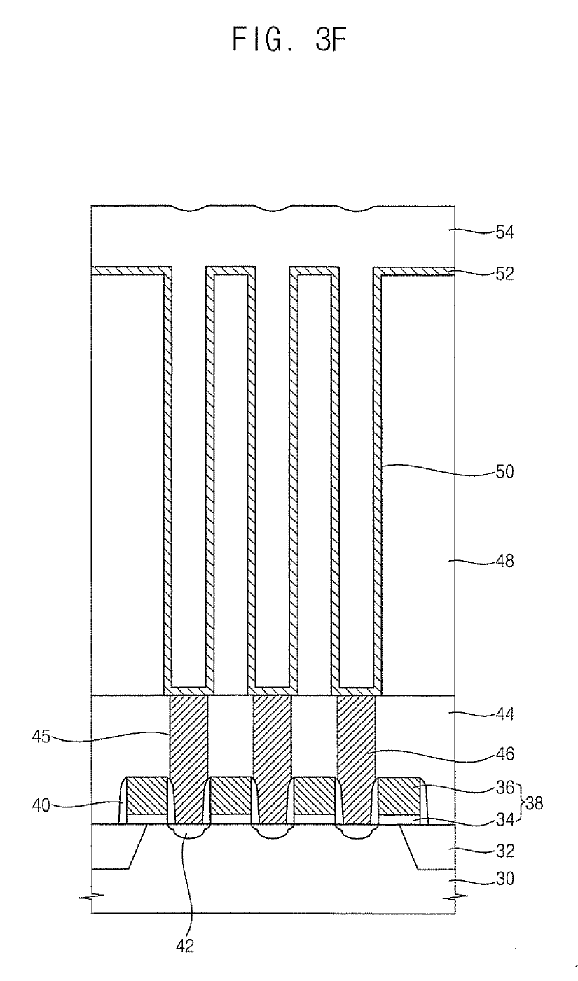

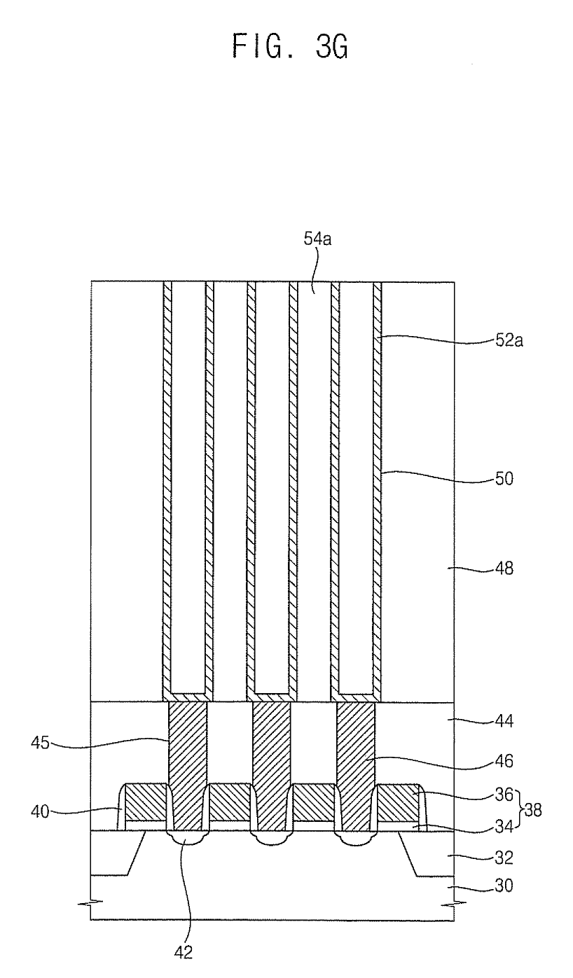

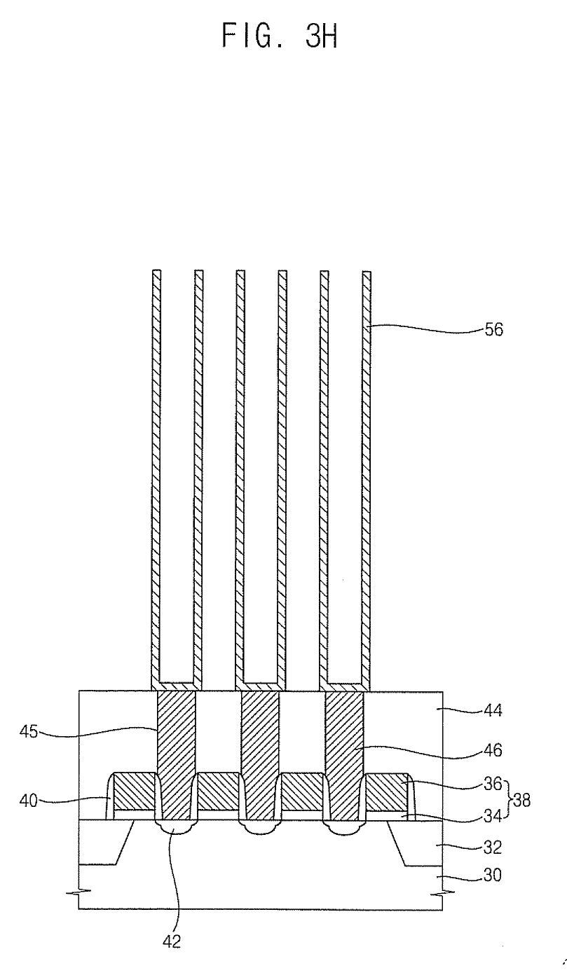

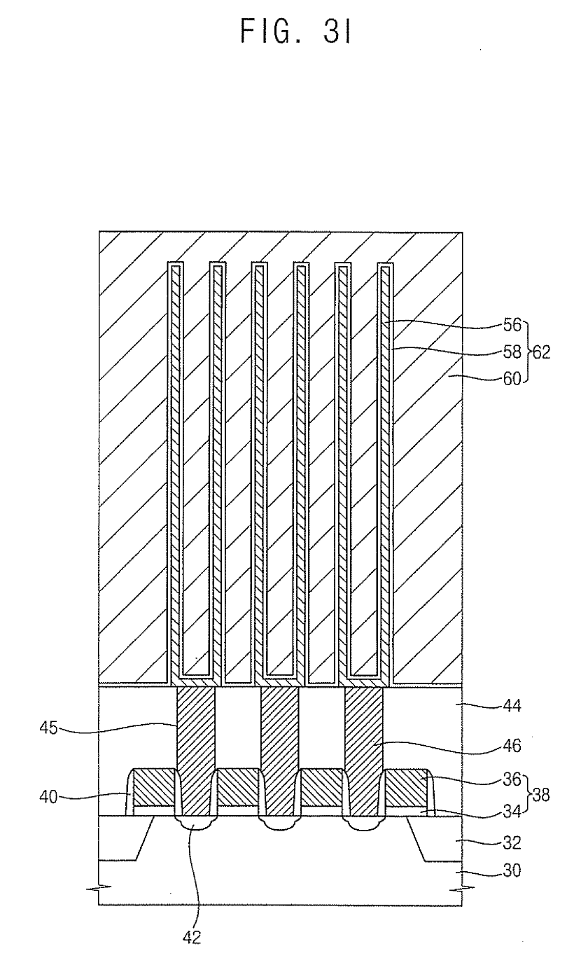

FIGS. 3A to 3I present cross-sectional views illustrating processes for methods of forming a capacitor for semiconductor devices according to some embodiments of the present invention. Referring to FIG. 3A, an isolation process may be performed on a semiconductor substrate 30 to form an insulation layer 32 on the substrate 30. The insulation layer 32 may electrically isolate a conductive structure from another conductive structure adjacent to the conductive structure on the substrate, and for at least this reason, the insulation layer 32 is hereinafter referred to as a device isolation layer. In some embodiments of the present embodiment, a trench isolation layer may be used as the device isolation layer 32 instead of a field oxide layer with respect to the degree of integration of the semiconductor device.

In more detail, a pad oxide layer and a pad nitride layer may be formed on the substrate 30 and a patterning process may be performed on the pad oxide layer and the pad nitride layer, thereby forming a pad oxide pattern and a pad nitride pattern through which the substrate 30 may be partially exposed. The substrate 30 may be partially etched by an etching process using the pad oxide pattern and the pad nitride pattern as an etching mask, thereby forming a trench on the substrate 30. A curing process may be further performed on the substrate 30 for curing any damage to the substrate 30 occurring during the etching process. An oxide material having desirable gap-fill characteristics may be filled into the trench by a plasma-enhanced CVD (PECVD) process, thereby forming an oxide layer in the trench. The oxide layer in the trench may be removed from the substrate by a planarization process, such as a chemical mechanical polishing (CMP) process, until a top surface of the pad nitride pattern is exposed, and the pad nitride pattern and the pad oxide pattern may be removed from the substrate 30 by an etching process using a suitable solution, such as a phosphate solution, as an etchant. Consequently, the oxide layer remains in the trench of the substrate 30, thereby forming the trench isolation layer as the device isolation layer. The substrate 30 may be divided into an active region and a field region by the trench isolation layer 32.

An insulation layer and a conductive layer may be sequentially formed on the substrate 30 including the trench isolation layer 32. For example, the insulation layer may include an oxide, metal oxide, metal oxynitride, etc. These materials can be used alone or in combination thereof. In some embodiments, even though the insulation layer includes a metal oxide having a small EOT, leakage current characteristics may be improved.

In some embodiments, the insulation layer includes a metal oxide and is formed through an ALD process. In some embodiments, the insulation layer includes zirconium oxide formed by an ALD process as described above with reference to FIGS. 1A to 1E. A post-treatment may be performed at a temperature in a range of about 10° C. to about 150° C. on the substrate 30 including the insulation layer. In some embodiments, a plasma oxidation process may be performed as the post-treatment with the process occurring at a temperature in a range of about 10° C. to about 150° C. and a pressure in a range of about 10 Pa to about 300 Pa for a period of time in a range of about 10 s to about 3,600 s by providing oxygen gas and an inert gas at a volume ratio in a range of about 1:1 to about 20:1. Accordingly, the composition ratio of zirconium and oxygen in the insulation layer including zirconium oxide may be about 1:2, and the impurities, including carbon (C), may be sufficiently removed from the insulation layer, and thus, may improve electrical characteristics of the insulation layer.

According to some embodiments of the present invention, the insulation layer may be formed into a multilayer structure including an aluminum oxide layer interposed between zirconium oxide layers. The conductive layer may include polysilicon, metal, metal nitride, metal silicide, etc. These materials can be used alone or in combination thereof. In some embodiments, a gate conductive pattern 36 may be formed into a multilayer structure for improving the efficiency of electrical characteristics thereof so that the conductive layer may be formed into the multilayer structure including a metal layer and a metal nitride layer The conductive layer and the insulation layer may be sequentially patterned, and a gate insulation layer 34 and the gate conductive pattern 36 may be formed in the active region of the substrate 30 to form a gate pattern 38 in the active region. The patterning process may be performed by an etching process using a photoresist pattern, or a hard mask pattern including nitride as an etching mask. When the patterning process is performed by an etching process using the hard mask pattern, the gate pattern 38 may further include the hard mask pattern on the gate conductive pattern 36.

A first ion implantation process may be performed on the substrate 30 using the gate pattern 38 as an ion implantation mask so that shallow junction regions may be formed at surface portions adjacent to the gate pattern 38. A spacer 40 including nitride may be formed at a sidewall of the gate pattern 38 by sequentially performing a deposition process and an etching process. A second ion implantation process may be performed onto the substrate 30 using the gate pattern 38 and the spacer 40 so that deep junction areas may be formed at surface portions of the substrate 30 adjacent to the spacer 40. As a result, source/drain regions may be formed into a lightly doped source/drain (LDD) structure at surface portions of the substrate 30. The source/drain regions 42 may be electrically connected to a lower electrode of a capacitor, as described in a subsequent procedure, however, a procedures that may be involved in a method of forming a bit line is omitted.

Referring to FIG. 38, an insulation interlayer 44 may be formed on the substrate 30 including the gate pattern 38 and may be patterned by a photolithography process to form a first opening 45 through which the source/drain regions 42 may be partially exposed. A conductive material, such as polysilicon and metal, may be filled into the first opening 45 thereby forming a contact pad 46 electrically connected to the lower electrode of the capacitor. The contact pad 46 may be formed in the first opening 45 by a deposition process and an implantation process, such as a CMP process and an etching process, against at least a significant portion of the surface of a conductive layer. In some embodiments, the contact pad 46 includes a first plug formed between the neighboring gate patterns 38, and a second plug electrically connected to the first plug.

The lower electrode of the capacitor may be formed into a cylindrical shape and may be electrically connected to the contact pad 46, as further described with reference to FIGS. 3C to 3H hereinafter. Referring to FIG. 3C, a mold layer 48a is formed on the insulation interlayer 44 including the contact pad 46 therein. The mold layer 48a may include an oxide and may be formed to a thickness the same as or substantially similar to the height of the lower electrode formed through a CVD process. For example, when the lower electrode has a height of about 1.65 μm, the mold layer 48a may also be formed to a thickness of about 1.65 μm.

Referring to FIG. 3D, the mold layer 48a may be patterned by a photolithography process to form a second opening 50 through which the contact pad 46 may be exposed. Particularly, a photoresist layer may be formed on the mold layer 48a and may be patterned into a photoresist pattern by a photolithography process in such a way that the mold layer 48a may be partially exposed through the photoresist pattern corresponding to the contact pad 46 under the mold layer 48a. The mold layer 48a may be partially etched using the photoresist pattern as an etching mask forming a mold layer 48 including the second opening 50 through which the contact pad 46 may be exposed.

Referring to FIG. 3E, a thin layer 52 may be formed on side and bottom surfaces of the second opening 50 and a top surface of the mold layer 48. The thin layer may include polysilicon, metal, metal nitride, etc. In some embodiments, the thin layer 52 includes a metal nitride, such as titanium nitride. In some embodiments of the present invention, the metal nitride may be deposited through a CVD process using titanium chloride (TiCl₄) gas and ammonium (NH₃) gas as a source gas at a temperature less than about 550° C. The thin layer 52 may also be formed by an ALD process or a sputtering process in addition to the CVD process.

Referring to FIG. 3F, a sacrificial layer 54 may be formed on a resultant structure including the thin layer 52, to a sufficient thickness to fill the second opening 50. In some embodiments, the sacrificial layer 54 has substantially the same etching selectivity as the mold layer 48. For example, the sacrificial layer 54 may include an oxide or photoresist composition.

Referring to FIG. 3G, the sacrificial layer 54 and the thin layer 52 may be at least partially removed from the resultant structure by an implantation process until a top surface of the mold layer 48 is exposed so that the sacrificial layer 54 and the thin layer 52 remain in the second opening 50. More specifically, the sacrificial layer 54 and the thin layer 52 may be separated by each node of a capacitor, which is referred to as a node separation. Hereinafter, the sacrificial layer 54 and the thin layer 52 remaining in the second opening after the node separation are referred to as residual sacrificial layer 54a and residual thin layer 52a, respectively. The implantation process may include a CMP process and an etching process against at least a significant portion of the sacrificial layer 54 and the thin layer 52.

Referring to FIG. 3H, the residual sacrificial layer 54a and the mold layer 48 may be removed from the substrate 30 so that only the residual thin layer 52a remains on the contact pad 46 as a cylindrical shape and the insulation interlayer 44 may be exposed. That is, the residual thin layer 52a makes contact with the contact pad 46 and may have a cylindrical shape so that a cylindrical lower electrode 56 of a capacitor may be formed on the contact pad 46. As a result, the lower electrode 56 may have a high aspect ratio. Alternatively, a plurality of lower electrodes 56 may be formed on a plurality of contact pads 46, each of the lower electrodes 56 being adjacent to each other in accordance with each of the contact pads 46. In some embodiments, the aspect ratio of the lower electrode 56 ranges from about 8 to about 12. For example, the lower electrode 56 may be formed to a height of about 1.65 μm and to a width of about 0.2 μm.

The mold layer 48 and the residual sacrificial layer 54a may be removed by a wet etching process using a low ammonium fluoride liquid (LAL) as an etchant. The LAL may be a mixture of ammonium fluoride (NH₄F), hydrogen fluoride (HF) and/or water (H₂O).

Referring to FIG. 31, a dielectric layer 58 may be continuously formed on a surface of the lower electrode 56 and a top surface of the insulation interlayer 44. In some embodiments, the dielectric layer 58 includes a metal oxide and may be formed to a relatively small EOT with a relatively small degree of current leakage. For example, the dielectric layer 58 may include zirconium oxide.

The dielectric layer 58 may be formed through the same or substantially similar procedures as described with reference to FIGS. 1A to 1E. Further, a post-treatment may also be performed on the dielectric layer 58 at a temperature in a range of about 10° C. to about 150° C. A plasma oxidation process may be performed as the post-treatment at a pressure in a range of about 10 Pa to about 300 Pa for a period of time in a range of about 10 s to about 3,600 s by providing oxygen gas and an inactive gas at a volume ratio in a range of about 20:1 to about 1:1. Under the above-described conditions, the composition ratio of zirconium and oxygen in the zirconium oxide may be about 1:2, and the impurities, including carbon (C), may be sufficiently removed from the dielectric layer 58 to improve electrical characteristics of the dielectric layer 58.

In some embodiments, the dielectric layer may be formed to a thickness in a range of about 5 Å to about 500 Å so that the EOT of the dielectric layer 58 is less than or equal to about 10 Å.

The dielectric layer 58 may also be formed into a multilayer structure, in which an aluminum oxide layer is interposed between the zirconium oxide layers, as would be understood to one of ordinary skill in the art. More specifically, an upper electrode 60 may be formed on a resultant structure including the dielectric layer 58. The upper electrode 60 may also include polysilicon, metal or metal nitride, as in the lower electrode 56. In some embodiments, the upper electrode 60 includes metal nitride. For example, the upper electrode 60 may include titanium nitride and may be formed through a CVD process using titanium chloride (TiCl₄) gas and ammonium (NH₃) gas as a source gas at a temperature no greater than about 550° C.

As described above, the lower electrode 56, the dielectric layer 58 and the upper electrode 60 may be sequentially formed on the substrate 30, thereby forming a capacitor 62 on the substrate 30. A zirconium oxide layer may be used as the dielectric layer 58 of the capacitor 62, so that the dielectric layer 58 may be formed to possess a relatively small EOT and/or a relatively small degree of current leakage and/or a relatively high dielectric constant, which may improve the electrical reliability of the capacitor 62.

Although the above-described embodiments discuss a cylindrical-shaped capacitor, a plate-shaped capacitor or any other configuration understood to those of ordinary skill in the art may also be formed using the same or a substantially similar dielectric layer including zirconium oxide.

Evaluation of Current Leakage

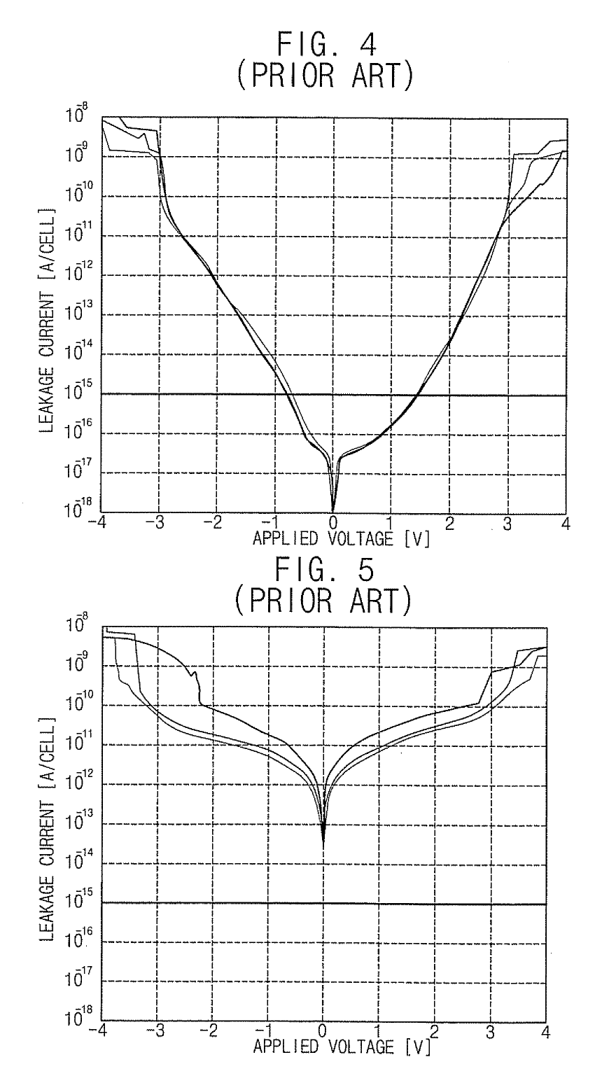

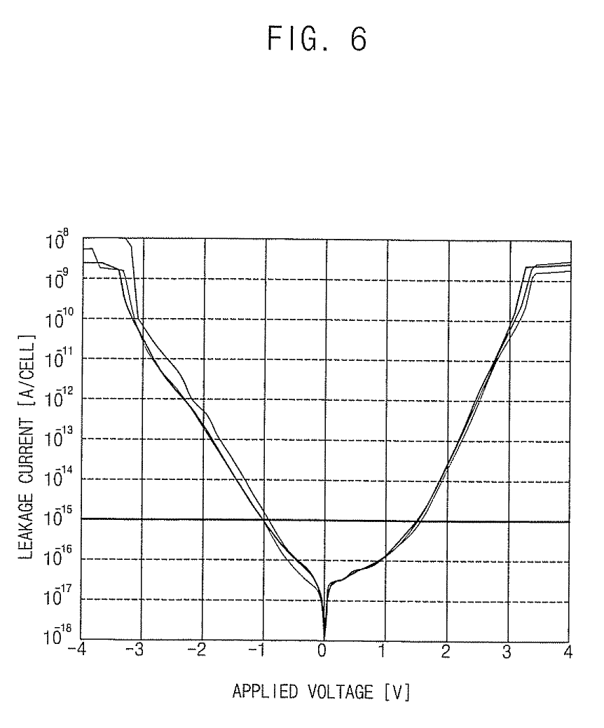

FIGS. 4 and 5 present graphs showing a change in leakage current in associated with voltage applied to the capacitor including a conventional dielectric layer, and FIG. 6 presents a graph showing a change in leakage current in association with voltage applied to the capacitor including a dielectric layer according to some embodiments of the present invention. Variation of the leakage current measured from sample capacitors I, II and III is shown in FIGS. 4, 5 and 6, respectively.

An ALD process was repeated on a lower electrode including titanium nitride to form a dielectric layer including zirconium oxide. An upper electrode including titanium nitride was formed on the dielectric layer, thereby forming sample capacitor 1. The ALD process included the following procedures performed in sequence. supplying TEMAZ into a processing chamber for 10 s; supplying argon gas into the processing chamber for 10 s; supplying ozone gas for 30 s; and supplying the argon gas for 10 s. The ALD process was also repeated on a lower electrode including titanium nitride, thereby forming a dielectric layer including zirconium oxide.

A plasma oxidation treatment was performed on the dielectric layer at a temperature of about 300° C. for 180 s, and an upper electrode including titanium nitride was formed on the dielectric layer, thereby forming sample capacitor II. The ALD process was also repeated on a lower electrode including titanium nitride to form a dielectric layer including zirconium oxide. A plasma oxidation treatment was performed on the dielectric layer at a temperature of about 20° C. for 180 s, and an upper electrode including titanium nitride was formed on the dielectric layer, thereby forming sample capacitor III.

As shown in FIGS. 4 to 6, the current leakage measured from sample capacitor III is greater than that measured from sample capacitor I and II. Accordingly, the measurement results shown in FIGS. 4 to 6 confirm that the post-treatment at a lower temperature may optimize the composition ratio of zirconium and oxygen in the zirconium oxide and may also reduce or remove the impurities, including carbon (C), from the dielectric layer.

According to embodiments of the present invention, an additional performance of a post-treatment after formation of a metal oxide layer at a lower temperature may sufficiently improve electrical characteristics of the metal oxide layer. More specifically, when including zirconium oxide, the metal oxide layer may be formed having a relatively small EOT. The metal oxide layer may be utilized as a gate insulation layer of a metal-oxide semiconductor (MOS) transistor, a dielectric layer of a flash memory device or a dielectric layer of a capacitor for a semiconductor device, and may improve the electrical characteristics of each of these devices.

Although embodiments of the present invention have been described, it is understood that the present invention should not be limited to these exemplary embodiments, but various changes and modifications can be made by one skilled in the art within the spirit and scope of the present invention as hereinafter claimed.

What is claimed is:

1. A method of forming a metal oxide layer, comprising:
forming a thin layer on a substrate, the thin layer comprising a metal oxide wherein a composition ratio of metal and oxygen in the metal oxide is about 1:2; and
performing a post-treatment on the thin layer at a temperature to reduce diffusion of oxygen from the metal oxide into the thin layer.

2. The method of claim 1, wherein the thin layer is formed through an atomic layer deposition (ALD) process, a sputtering process or a chemical vapor deposition (CVD) process.

3. The method of claim 2, wherein the ALD process is performed at a temperature in a range of about 200° C. to about 400° C. under a pressure in a range of about 0.1 Torr to about 3.0 Torr.

4. The method of claim 1, wherein the thin layer comprises zirconium oxide.

5. The method of claim 4, wherein the method further comprises using a reactant comprising a zirconium precursor and an oxidizing agent, wherein the reactant is selected from the group consisting of zirconium butoxide(Zr(OtBu)₄), tetrakis ethylmethylamino zirconium, (TEMAZ, Zr[N(CH₃)(C₂H₅)₄]), zirconium ethoxide (Zr(OEt)₄), zirconium isopropoxide (Zr(OC₃H₇)₄), tetramethyl heptanedionato zirconium (Zr[TMHD]₄, Zr(C₁₁H₁₉O₂)₄) and combinations thereof, and the oxidizing agent is selected from the group consisting of ozone (O₃), oxygen (O₂), water vapor (H₂O), plasma-activated oxygen (O₂), remote plasma-activated oxygen (O₂) and combinations thereof.

6. The method of claim 1, wherein the post-treatment is performed at a temperature in a range of about 10° C. to about 300° C.

7. The method of claim 6, wherein the post-treatment comprises a plasma oxidation treatment and oxygen gas is utilized as a source gas and an inert gas is utilized as a carrier gas.

8. The method of claim 7, wherein the oxygen gas and the inert gas are provided at a volume ratio in a range of about 1:1 to about 20:1.

9. The method of claim 7, wherein the plasma oxidation treatment is performed under a pressure in a range of about 10 Pa to about 300 Pa at an applied power in a range of about 50 W to about 1000 W for a period of time in a range of about 10 s to about 3,600 s.

10. The method of claim 1, wherein the thin layer is a multi-layered structure.

11. The method of claim 10, wherein the thin layer further comprises aluminum oxide.

12. The method of claim 1, wherein the thin layer is a dielectric layer of a capacitor for a semiconductor device, a gate oxide insulation layer of a metal-oxide semiconductor (MOS) transistor or a dielectric layer of a flash memory device.

13. A method of forming a zirconium oxide layer, comprising:
forming a thin layer on a substrate, the thin layer comprising zirconium oxide; and
performing a post-treatment on the thin layer at a temperature in a range of about 20° C. to about 300° C. using an atomic layer deposition process wherein a composition ratio of zirconium and oxygen in the zirconium oxide is about 1:2 to provide a zirconium oxide layer having reduced oxygen diffusion into the thin layer, a smaller equivalent oxide thickness or a combination thereof, compared to a zirconium oxide layer formed using a conventional process.

14. A method of forming a capacitor for a semiconductor device, comprising:
forming a lower electrode on a substrate;
forming a thin layer on the lower electrode, wherein the thin layer comprises zirconium oxide;
performing a post-treatment on the thin layer at a temperature wherein a reduction of diffusion of oxygen from the zirconium oxide into the thin layer results and a composition ratio of zirconium and oxygen in the zirconium oxide is about 1:2 to provide a dielectric layer; and
forming an upper electrode on the dielectric layer.

15. The method of claim 14, wherein the lower and upper electrode each independently comprise polysilicon, metal, metal nitride and combinations thereof.

16. The method of claim 14, wherein the thin layer is formed using an atomic layer deposition (ALD) process performed at a temperature in a range of about 200° C. to about 400° C. under a pressure in a range of about 0.1 Torr to about 3.0 Torr using a reactant comprising a zirconium precursor and an oxidizing agent.

17. The method of claim 16, wherein the reactant is selected from the group consisting of zirconium butoxide(Zr(OtBu)₄), tetrakis ethylmethylamino zirconium, (TEMAZ, Zr[N(CH₃)(C₂H₅)₄]), zirconium ethoxide (Zr(OEt)₄), zirconium isopropoxide (Zr(OC₃H₇)₄), tetramethyl heptadionato zirconium (Zr[TMH D]₄, Zr(C₁₁H₁₉O₂)₄) and combinations thereof, and the oxidizing agent is selected from the group consisting of ozone (O₃), oxygen (O₂), water vapor (H₂O), plasma-activated oxygen (O₂), remote plasma-activated oxygen (O₂) and combinations thereof.

18. The method of claim 14, wherein the post-treatment is performed at a temperature in a range of about 10° C. to about 150° C.

19. The method of claim 18, wherein the post-treatment comprises a plasma oxidation treatment wherein oxygen gas is utilized as a source gas and an inert gas is utilized as a carrier gas and the plasma oxidation treatment is performed under a pressure in a range of about 100 Pa to about 300 Pa at an applied power in a range of about 300 W to about 1000 W for a period of time in a range of about 10 s to about 3,600 s, and the oxygen gas and the inert gas are provided at a volume ratio in a range of about 1:1 to about 20:1 in the plasma oxidation treatment.

20. The method of claim 14, wherein the thin layer further comprises aluminum oxide.

21. The method of claim 14, wherein the dielectric layer is formed to a thickness in a range of about 5 Å to about 500 Å.

22. A method of forming a capacitor for a semiconductor device, comprising:
forming a mold layer on a semiconductor substrate, wherein the mold layer has an opening through which the substrate is at least partially exposed;
forming a first thin layer on side and bottom surfaces of the opening and a top surface of the mold layer, wherein the first thin layer comprises titanium nitride;
forming a sacrificial layer on a resultant structure comprising the first thin layer to a thickness to fill the opening;
removing the sacrificial layer and the first thin layer to expose a top surface of the mold layer wherein the sacrificial layer and the first thin layer remain in the opening thereby providing a node separation of the first thin layer;
removing a residual sacrificial layer in the opening and the mold layer from the substrate wherein the node-separated first thin layer is formed into a lower electrode;
forming a second thin layer on the lower electrode to a substantially uniform thickness by an atomic layer deposition (ALD) process, wherein the second thin layer comprises zirconium oxide;
performing a post-treatment on the second thin layer at a temperature in a range of about 10° C. to about 150° C., wherein a composition ratio of zirconium and oxygen in the zirconium oxide is about 1:2 thereby transforming the second thin layer into a dielectric layer; and
forming an upper electrode on the dielectric layer.

23. The method of claim 22, wherein the post-treatment comprises a plasma oxidation treatment, wherein oxygen gas is utilized as a source gas and an inert gas is utilized as a carrier gas and the plasma oxidation treatment is performed under a pressure in a range of about 100 Pa to about 300 Pa at an applied power in a range of about 300 W to about 1000 W for a period of time in a range of about 10 s to about 3,600 s, and the oxygen gas and the inactive gas are provided at a volume ratio in a range of about 1:1 to about 20:1 in the plasma oxidation treatment.

24. The method of claim 22, wherein the second thin layer further comprises aluminum oxide.

25. The method of claim 22, wherein the dielectric layer has a thickness in a range of about 5 Å to about 500 Å.
